(19) United States
(12) Patent Application Publication
(10) Pub. No.: US 2004/0080305 A1
(43) Pub. Date: Apr. 29, 2004

(54) Power on detect circuit

(76) Inventors: Yu-Tong Lin, Taichung (TW); Yung-Pin Lee, Junghe City (TW)

Correspondence Address: RABIN & Berdo, PC, 1101 14TH STREET, NW, SUITE 500, WASHINGTON, DC, 20005, US

(21) Appl. No.: 10/281,980

(22) Filed: Oct. 29, 2002

(51) Int. Cl. H01L 27/10

(52) U.S. Cl. 323/312

(57) ABSTRACT

A power on detect circuit. The power on detect circuit is designed for detecting low power on voltage and having low temperature coefficient of power on voltage. Detected power on voltage range is insensitive to process and temperature. The power on detect circuit includes two MOS transistors, one has a larger aspect ratio and is coupled to a voltage source by two series resistors, the first resistor and the second resistor, and the other has a lower aspect ratio and is coupled to the voltage source by a resistor, the third resistor. A comparator senses out voltage difference the first resistor and the third resistor to generate a power on reset signal.

### BACKGROUND OF THE INVENTION

1. Field of the Invention

The present invention relates to power on detect circuits, and particularly to power on detect circuits detecting low voltage.

2. Description of the Related Art

FIG. 1 shows a schematic diagram of the prior art. The power on detect circuit 100 in FIG. 1 includes a voltage detect circuit 110 and a RC-filter 120.

The voltage detect circuit 110 includes a PMOS transistors MP1, NMOS transistors MN1, MN2, and a resistor R1. The NMOS transistor MN1 and PMOS MP1 transistor form a voltage reference circuit. The source and gate of the PMOS transistor MP1 are both coupled to a node A to which the drain and gate of the NMOS transistor MN2 are both coupled. The node A is coupled to the gate of the NMOS transistor MN2. The NMOS transistor MN2 and the resistor R1 form a detect circuit. A resistor R1 is coupled between the drain of the NMOS transistor MN2 and the voltage source VCC.

The PMOS transistors MP1 and the NMOS transistor MN1 form a voltage divider to generate a reference voltage VREF at the node A. The reference voltage VREF is determined by threshold voltages Vthn and Vthp of the NMOS transistor MN1 and of the PMOS transistor MP1 respectively. The NMOS transistor MN2 is in the configuration of common-source with a passive load R1 for outputting the detecting result at node B.

When process or temperature results in variations of the threshold voltage Vthn of the NMOS transistor MN2, the NMOS transistor MN1 has the same variation in the threshold voltage Vthn. Thus, the reference voltage VREF has the variation resulted from the threshold voltage Vthn of the NMOS transistor MN1. Under the condition that voltage VCC remains the same, the variation of reference voltage VREF compensates the variation of the threshold voltage Vthn of the NMOS transistor MN2. Therefore, the voltage of the node B remains constantly without suffering from the variation of the threshold voltage Vthn.

There is a disadvantage, a worst case that the threshold voltage Vthp of the PMOS transistor MP1 varies in the same attitude as that of the NMOS transistor MN1 does. Thus, the variation resulted from the threshold voltage Vthp of the PMOS transistor MP1 impedes the compensation by the NMOS transistor MN1. The worst case occurs in PFNS/PSNS process.

Another disadvantage in the power on detect circuit 100 occurs when the voltage source VCC is scaled down by the advance process. Owing to the threshold voltages Vthn and Vthp not scaled down with process, variations of the detect voltage are very large and voltage overhead is too high.

FIG. 2 shows a schematic diagram for the other prior art. The voltage circuit 200 includes BJT Q1, Q2, resistors R1, R2, R3, R4, and a comparator 22. The base and the collector the BJT Q1 are both tied to ground. The collector of the BJT Q1 is coupled to the resistor R1. The resistor R2 is in series with the resistor R1 at node A. The base and the collector of the BJT Q2 are both tied to ground. The collector of the BJT Q2 is coupled to the resistor R2 at node B. The resistor R4 is coupled between the resistors R2, R3 and the voltage source VCC. A non-inverting input of the comparator 22 is coupled to the node A, and an inverting input of the comparator 22 is coupled to the node B. The emitter area of the BJT transistor Q1 is N times that of the BJT transistor Q2. The resistors R2 and R3 have the same resistance.

When the voltage source VCC is powered up to a detect voltage range, the voltages VA approximates the voltage VB.

The detected voltage of the power on detect circuit 200 is given by of the junction voltage VEB2 of the BJT transistor Q2 and the voltage drop of the resistor R3. The temperature coefficient of the junction voltage VEB2 is negative. The voltage drop of the resistor R1 is a voltage difference of the voltages VEB2 and VEB1, the thermal voltage multiplied by a factor. Because R1=R3 and VA=VB, the temperature coefficient of the voltage drop of the resistor R3 is positive and proportional to a resistance ratio ((R3/R1)+1) timed by ln(N). A zero temperature coefficient of the detect voltage of the power on detect circuit 200 can be achieved by adjusting the emitter area ratio N and the resistance ratio R3/R1.

The resistance of the resistor R4 is used to tune the detect voltage of the voltage source VCC to a required level. The comparator 22 is utilized for sensing out the voltage VA and VB of the nodes A and B respectively, and the output voltage Vout of the comparator 22 will not transit state until the voltage source VCC is powered up to a detect voltage range.

With process shrinks down to 0.13 um, the required detect voltage range is 0.65V to 0.8V, below the normal voltage that BJT transistors can work. There is a need for a power on detect circuit that has a detect voltage for low voltage design.

### SUMMARY OF THE INVENTION

It is therefore an object of the present invention to provide a power on detect circuit for low voltage.

To achieve the above objects, the present invention provides the power on detect circuit with MOS transistors having advantages of low voltage overheads, as shown in FIG. 3.

The voltage detect circuit includes a first MOS transistors MN1, a second MOS transistor MN2, a first resistor R1, a second resistor R2, a third resistor R3, a fourth resistor R4, and a comparator 22. The gate and the drain the first MOS transistor are tied together. The drain of the first MOS transistor is coupled to the first resistor. The second resistor is in series with the first resistor at a first node A. The gate and the drain of the second MOS transistor are tied together. The drain of the second MOS transistor is coupled to the third resistor at a second node B. The area ratio of the first MOS transistor is made N multiple of that of the second MOS transistor.

The fourth resistor R4 is coupled between the second and third resistors and a voltage source. A positive terminal of the comparator is coupled to the first node A, and a negative terminal of the comparator is coupled to the second node B.

The power on detect circuit further includes a fifth resistor R5 and a sixth resistor R6. The fifth resistor is coupled between the source of the first MOS transistor M1 and a first voltage source A. The sixth resistor is coupled between the source of the second MOS transistor M2 and the second voltage source B.

### BRIEF DESCRIPTION OF THE DRAWINGS

The aforementioned objects, features and advantages of this invention will become apparent by referring to the following detailed description of the preferred embodiment with reference to the accompanying drawings, wherein:

FIG. 1 shows a schematic diagram of the prior art.

FIG. 2 shows a schematic diagram for the other prior art.

FIG. 3 shows a schematic diagram of the first embodiment.

FIG. 4 is a timing diagram of power supply.

FIG. 5 shows a diagram of detect voltages versus process variations.

FIG. 6 shows a diagram of detect voltages versus temperature variations.

FIG. 7 shows power on detect voltages of the present embodiment compared to the prior art.

FIG. 8 shows another schematic diagram of the first embodiment.

FIG. 9 shows a schematic diagram of the second embodiment.

FIG. 10 shows another schematic diagram of the second embodiment.

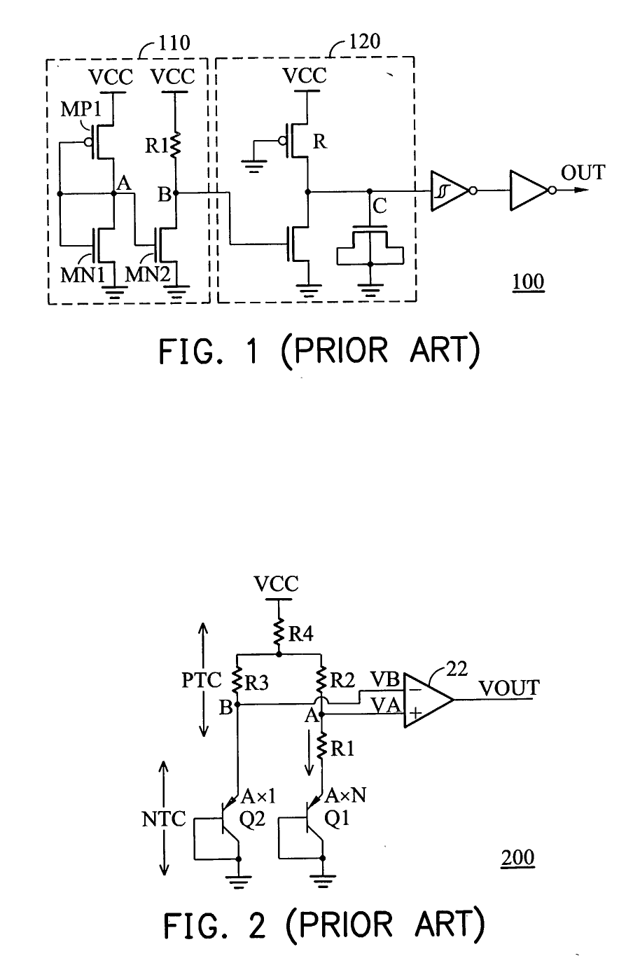

### DETAILED DESCRIPTION OF THE INVENTION

The First Embodiment

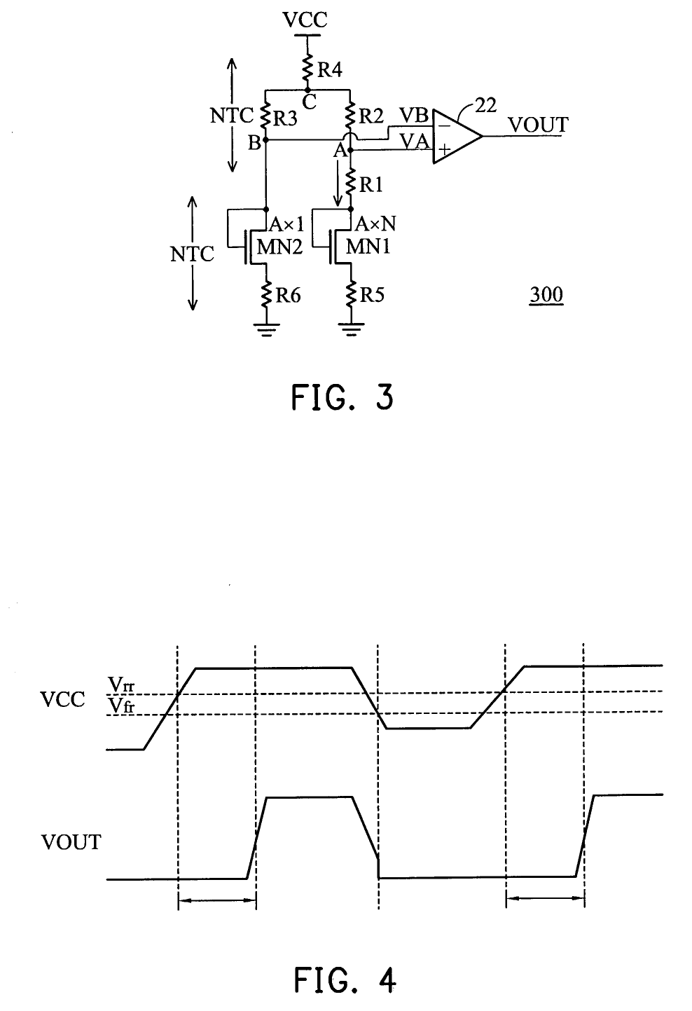

FIG. 3 shows a schematic diagram of the first embodiment. The voltage detect circuit 300 includes NMOS transistors MN1, MN2, resistors R1, R2, R3, R4, R5, R6 and an comparator 22. The gate and the drain the NMOS transistor MN1 are tied together. The drain of the NMOS transistor MN1 is coupled to the resistor R1. The resistor R2 is in series with the resistor R1 at node A. The gate and the drain of the NMOS transistor MN2 are tied together. The drain of the NMOS transistor MN2 is coupled to the resistor R3 at node B. The aspect ratio of the NMOS transistor MN1 is made N times larger than that of the NMOS transistor MN2. The resistor R4 is coupled between the resistors R2, R3 and the voltage source VCC. A non-inverting terminal of the comparator 22 is coupled to the node A, and an inverting terminal of the comparator 22 is coupled to the node B. The resistor R5 is coupled between the source of the NMOS transistor MN1 and ground. The resistor R6 is coupled between the source of the NMOS transistor MN2 and ground.

FIG. 4 is a timing diagram of power supply. Initially, the voltage source VCC is below the voltage Vf r such that the voltage VA is lower than the voltage VB, and the output voltage Vout of the comparator 22 is at low level. Until the voltage source VCC rises to the voltage Vfr, the output voltage Vout of the comparator 22 is at low level margin.

During the voltage source VCC rises from the voltage Vfr to the voltage Vrr, there is a crossing point of the voltage VB and the voltage VA, then the voltage VA is higher than the voltage VB. The non-inverting terminal and the inverting terminal of the comparator 22 sense out the crossing over of the voltage VA and VB, the output voltage Vout of the comparator 22 has a transition from low level to high level.

When the voltage source VCC rises to the voltage Vrr, the output voltage Vout of the comparator 22 is at high level margin.

Compared with the power on detect circuit 200 in FIG. 2, the NMOS transistor MN1 and MN2 is used to ensure the power on detect circuit 300 to detect voltage Vrr=0.8V and Vfr=0.65V, below normal voltage by which BJT transistor can work.

The resistance of the resistor R4 is designed to tune the voltages Vfr and Vrr to meet a required voltages.

When the voltage source VCC is between the voltage Vfr and the voltage Vrr, the voltage VA approximates to the voltage VB. The voltage drop of the resistor R1 is close to a voltage difference (Vgs2−Vgs1) between the gate-to-drain voltages Vgs2 and Vgs1 of the NMOS transistors MN2 and MN1 respectively. And, the current in the resistors R1, R2, and R3 are nearly equal. Thus, the voltage drop of the resistor R3 approximates to the voltage difference (R3/R1) (Vgs2−Vgs1). R3/R1 is a ratio of the resistance of the resistor R3 to that of the resistor R1.

The voltage difference (Vgs2−Vgs1) has a negative temperature coefficient. The gate-to-drain voltage Vgs2 has a negative temperature coefficient. The ratio R3/R1 is used to adjust the temperature coefficient of the voltage Vrr and Vfr. The temperature coefficient of the voltage Vrr and Vfr is reduced by decreasing the ratio of the resistance R1 to R2.

The temperature coefficient of the gate-to-drain voltage Vgs2 is reduced by source degeneration of the NMOS transistor MN2. The resistor R6 is used to realize source degeneration of the NMOS transistor MN2. Similarly, the resistor R5 functions as the same.

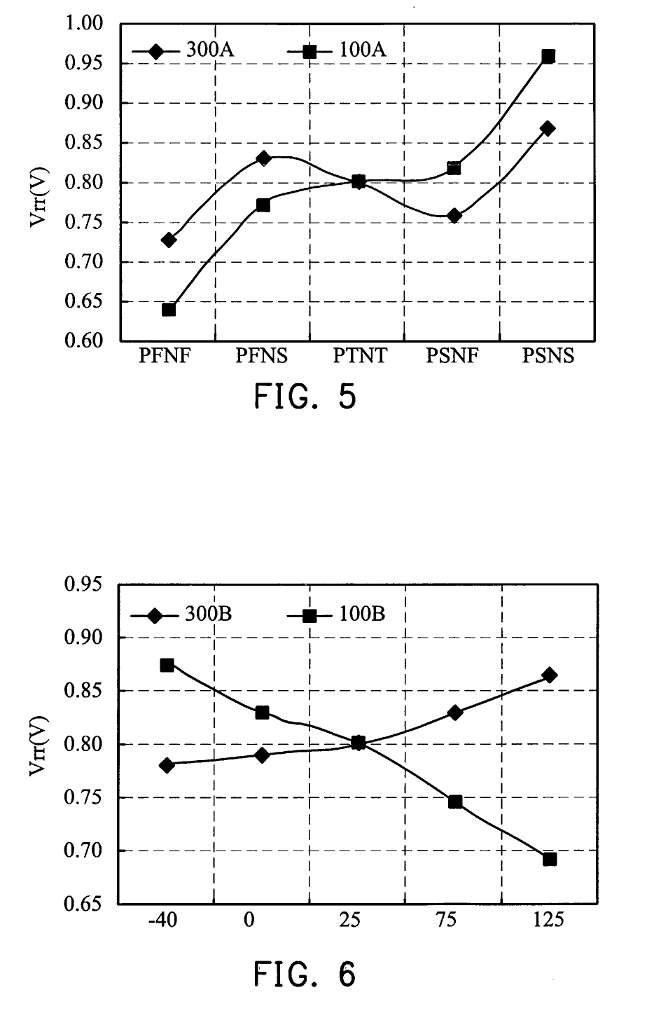

FIG. 5 shows a diagram of detect voltages versus process variations. As shown in FIG. 5, the curve 100A and 300A represents the detect voltage Vrr of the power on detect circuit 100 and 300 respectively. Processes PFNF, PFNS, PTNT, PSNF, and PSNS represent various kinds of extreme variations in PMOS and NMOS transistors. The power on detect circuit 300 has narrower variations than that the power on detect circuit 100 has.

FIG. 6 shows a diagram of detect voltages versus temperature variations. The temperature varies from −40° C. to 125° C. As shown in FIG. 6, the curve 100B and 300B represents the detect voltage Vrr of the power on detect circuit 100 and 300 respectively. The power on detect circuit 300 much lower temperature coefficient than that of the power on detect circuit 100 has.

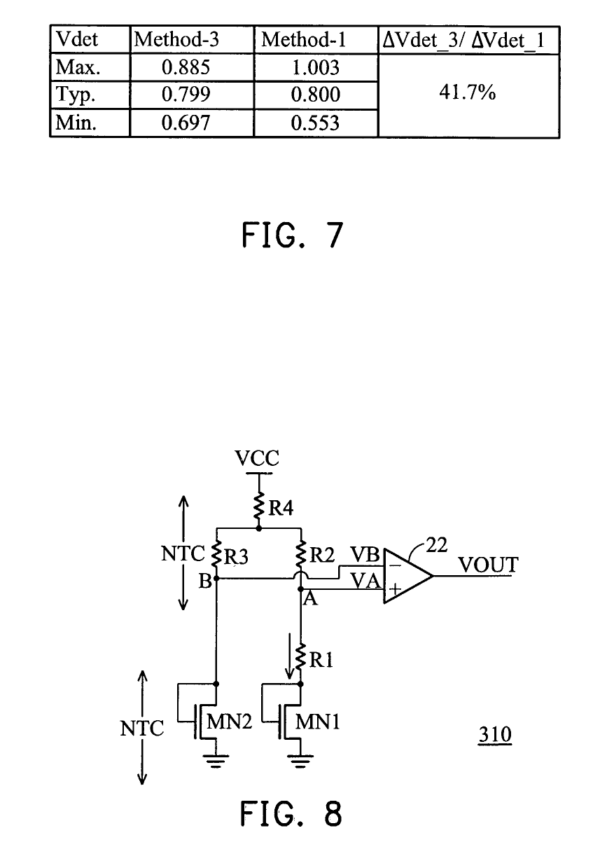

FIG. 7 shows power on detect voltages of the present embodiment compared to the prior art. The maximum and minimum power on detect voltages are the extreme cases that given by processes PFNF, PFNS, PTNT, PSNF, and PSNS, temperature varying from −40° C. to 125° C., and resistor varying 20%. As shown in FIG. 7, variations of the power on detect circuit 300 is much narrower 58.3% than the power on detect circuit 100.

FIG. 8 shows another schematic diagram of the first embodiment. The voltage detect circuit 310 includes NMOS transistors MN1, MN2, resistors R1, R2, R3, R4 and a comparator 22. The source of the NMOS transistor MN2 is coupled to ground directly, and so does the NMOS transistor MN1.

The Second Embodiment

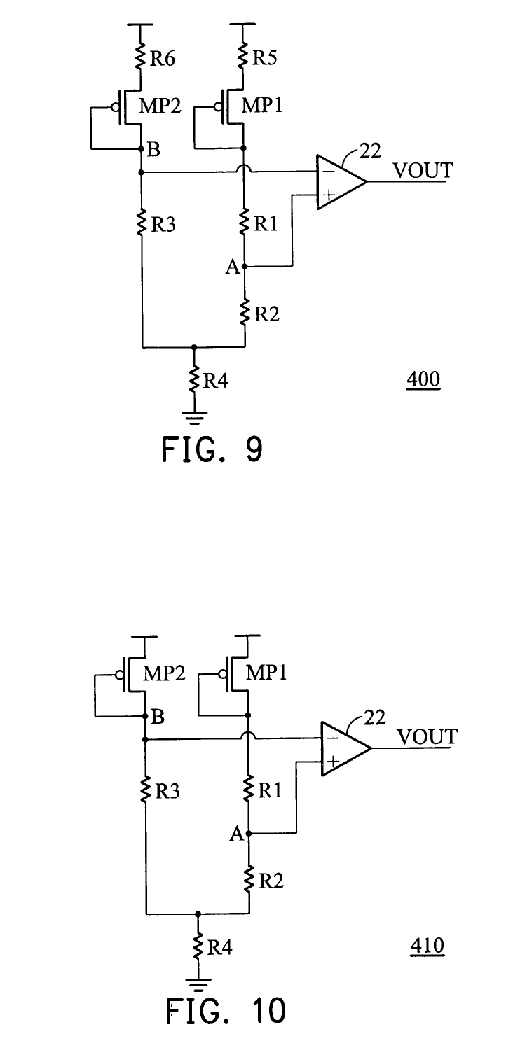

FIG. 9 shows a schematic diagram of the second embodiment. The voltage detect circuit 400 includes PMOS transistors MP1, MP2, resistors R1, R2, R3, R4, R5, R6 and a comparator 22. The gate and the drain of the PMOS transistor MP1 are tied together. The drain of the PMOS transistor MP1 is coupled to the resistor R1. The resistor R2 is in series with the resistor R1 at node A. The gate and the drain of the PMOS transistor MP2 are tied together. The drain of the PMOS transistor M2 is coupled to the resistor R3 at node B. The resistor R4 is coupled between the resistors R2, R3 and ground. A non-inverting terminal of the comparator 22 is coupled to the node A, and an inverting terminal of the comparator 22 is coupled to the node B. The resistor R5 is coupled between the source of the PMOS transistor MP1 and the voltage source VCC. The resistor R6 is coupled between the source of the PMOS transistor MP2 and the voltage source.

FIG. 10 shows another schematic diagram of the second embodiment. The voltage detect circuit 410 includes PMOS transistors MP1, MP2, resistors R1, R2, R3, R4 and a comparator 22. The source of the PMOS transistor MP2 is coupled to the voltage source VCC directly, and so does the NMOS transistor MN1.

Although the present invention has been described in its preferred embodiment, it is not intended to limit the invention to the precise embodiment disclosed herein. Those who are skilled in this technology can still make various alterations and modifications without departing from the scope and spirit of this invention. Therefore, the scope of the present invention shall be defined and protected by the following claims and their equivalents.

What is claimed is:

1. A power-on detect circuit comprising:
a first MOS transistor having a drain, a gate, and a source, wherein the gate is coupled to the drain, and the source is coupled to a first voltage source;
a first resistor having a terminal coupled to the drain of the first MOS transistor;
a second resistor having a terminal coupled to the other terminal of the first resistor;
a second MOS transistor having a drain, a gate, and a source, wherein the gate is coupled to the drain, and the source is coupled to the first voltage source;
a third resistor having a terminal coupled to the drain of the second MOS transistor;
a fourth resistor having a terminal coupled to the other terminal of the second resistor and the other terminal of the third resistor and having the other terminal to a second voltage source; and
a comparator having a first terminal coupled to the drain of the second MOS transistor and a second terminal coupled to a junction of the first resistor and the second resistor.

2. The power-on detect circuit as claimed in claim 1, wherein
the first MOS transistor is a NMOS transistor;
the second MOS transistor is a NMOS transistor;
the first voltage source is a low voltage; and
the second voltage source is a high voltage.

3. The power-on detect circuit as claimed in claim 2 further comprising:
a fifth resistor coupled between the source of the first MOS transistor and the first voltage source; and
a sixth resistor coupled between the source of the second MOS transistor and the first voltage source.

4. The power-on detect circuit as claimed in claim 1, wherein
the first MOS transistor is a PMOS transistor;
the second MOS transistor is a PMOS transistor;
the first voltage source is a high voltage; and
the second voltage source is a low voltage.

5. The power-on detect circuit as claimed in claim 4 further comprising:
a fifth resistor coupled between the source of the first MOS transistor and the first voltage source; and
a sixth resistor coupled between the source of the second MOS transistor and the first voltage source.

6. A power-on detect circuit comprising:
a first MOS transistor having a drain, a gate, and a source, wherein the gate is coupled to the drain;
a first resistor having a terminal coupled to the drain of the first MOS transistor;
a second resistor having a terminal coupled to the other terminal of the first resistor;
a second MOS transistor having a drain, a gate, and a source, wherein the gate is coupled to the drain;
a third resistor having a terminal coupled to the drain of the second MOS transistor;
a fourth resistor having a terminal coupled to the other terminal of the second resistor and the other terminal of the third resistor and having the other terminal to a second voltage source;
a comparator having a first terminal coupled to the drain of the second MOS transistor and a second terminal coupled to a junction of the first resistor and the second resistor
a fifth resistor coupled between the source of the first MOS transistor and a first voltage source; and
a sixth resistor coupled between the source of the second MOS transistor and the first voltage source.

7. The power-on detect circuit as claimed in claim 1, wherein
the first MOS transistor is a NMOS transistor;
the second MOS transistor is a NMOS transistor;
the first voltage source is a low voltage; and
the second voltage source is a high voltage.

8. The power-on detect circuit as claimed in claim 1, wherein
the first MOS transistor is a PMOS transistor;
the second MOS transistor is a PMOS transistor;
the first voltage source is a high voltage; and
the second voltage source is a low voltage.
